(19) United States
(12) Patent Application Publication
(10) Pub. No.: US 2025/0157973 A1
(43) Pub. Date: May 15, 2025

(54) SYSTEMS AND METHODS FOR REDUCING SEMICONDUCTOR DEVICE DELAMINATION

(71) Applicant: Advanced Micro Devices, Inc., Santa Clara, CA (US)

(72) Inventor: Hsiang-Wei Liu, Hsinchu (TW)

(73) Assignee: Advanced Micro Devices, Inc., Santa Clara, CA (US)

(21) Appl. No.: 18/506,375

(22) Filed: Nov. 10, 2023

(51) Int. Cl. H01L 23/00

(52) U.S. Cl. CPC H01L 24/19; H01L 24/20; H01L 2224/19; H01L 2224/2101

(57) ABSTRACT

A method for reducing semiconductor device delamination can include depositing a top barrier layer on top of a metal layer plating a bottom barrier layer. The method can also include depositing dielectric material on top of the top barrier layer and adjacent to the metal layer and the bottom barrier layer. Various other methods and systems are also disclosed.

### BACKGROUND

A semiconductor device is an electronic component that relies on the electronic properties of a semiconductor material (primarily silicon, germanium, and gallium arsenide, as well as organic semiconductors) for its function. Its conductivity lies between conductors and insulators. Semiconductor devices have replaced vacuum tubes in most applications. They conduct electric current in the solid state, rather than as free electrons across a vacuum (typically liberated by thermionic emission) or as free electrons and ions through an ionized gas.

In electronics, a wafer (also called a slice or substrate) is a thin slice of semiconductor, such as a crystalline silicon (c-Si), used for the fabrication of integrated circuits and, in photovoltaics, to manufacture solar cells. The wafer serves as the substrate for microelectronic devices built in and upon the wafer. It can undergo various microfabrication processes, such as doping, ion implantation, etching, thin-film deposition of various materials, and photolithographic patterning. Finally, the individual microcircuits can be separated by wafer dicing and packaged as an integrated circuit.

Delamination is a separation along a plane parallel to a surface, as in the separation of a coating from a substrate or the layers of a coating from each other or a horizontal splitting, cracking, or separation near the upper surface. Semiconductor devices can experience delamination between wafers that make up those devices, which can negatively impact device performance.

### BRIEF DESCRIPTION OF THE DRAWINGS

The accompanying drawings illustrate a number of exemplary implementations and are a part of the specification. Together with the following description, these drawings demonstrate and explain various principles of the present disclosure.

FIG. 1 is a flow diagram of an example method for reducing semiconductor device delamination.

FIG. 2A is a block diagram of an example semiconductor device resulting from via formation in a dielectric material.

FIG. 2B is a block diagram of an example semiconductor device resulting from barrier layer deposition.

FIG. 2C is a block diagram of an example semiconductor device resulting from redistribution layer line definition by photoresist deposition.

FIG. 2D is a block diagram of an example semiconductor device resulting from metal plating of vias and redistribution layer lines.

FIG. 2E is a block diagram of an example semiconductor device resulting from photoresist removal and barrier layer etching.

FIG. 2F is a block diagram of an example semiconductor device resulting from repeated redistribution layer formation and addition of a bump or solder ball.

FIG. 3A is a block diagram of an example semiconductor device resulting from via formation in a dielectric material.

FIG. 3B is a block diagram of an example semiconductor device resulting from barrier layer deposition.

FIG. 3C is a block diagram of an example semiconductor device resulting from metal plating and additional barrier layer deposition.

FIG. 3D is a block diagram of an example semiconductor device resulting from photoresist deposition.

FIG. 3E is a block diagram of an example semiconductor device resulting from etching.

FIG. 3F is a block diagram of an example semiconductor device resulting from repeated redistribution layer formation and addition of a bump or solder ball.

Throughout the drawings, identical reference characters and descriptions indicate similar, but not necessarily identical, elements. While the examples described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

The present disclosure is generally directed to systems and methods for reducing semiconductor device delamination. For example, by depositing a top barrier layer on top of a metal layer plating a bottom barrier layer and depositing dielectric material on top of the top barrier layer and adjacent to the metal layer and the bottom barrier layer, the top barrier layer can promote adhesion of the dielectric material to a lower layer, reduce delamination, and improve performance of a semiconductor device.

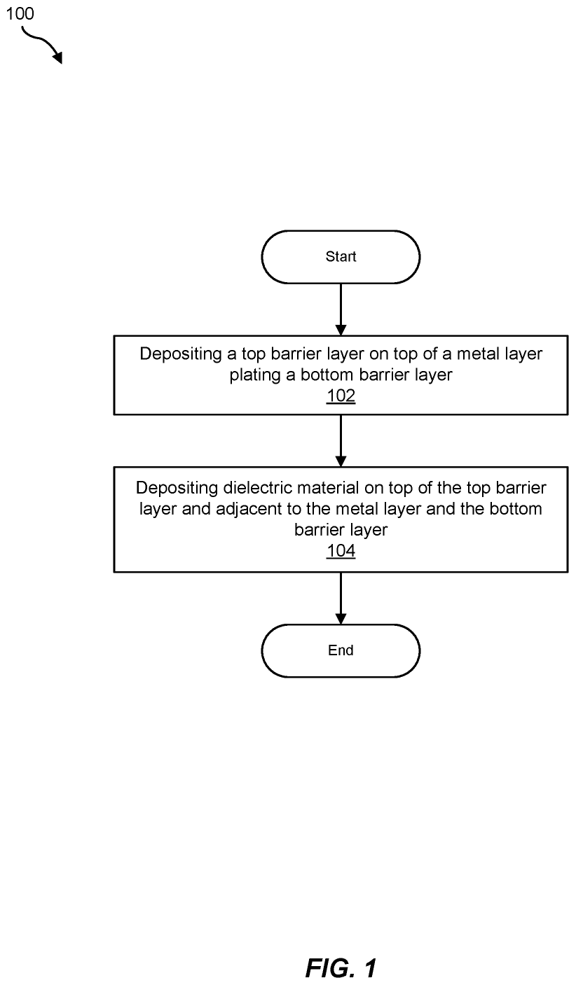

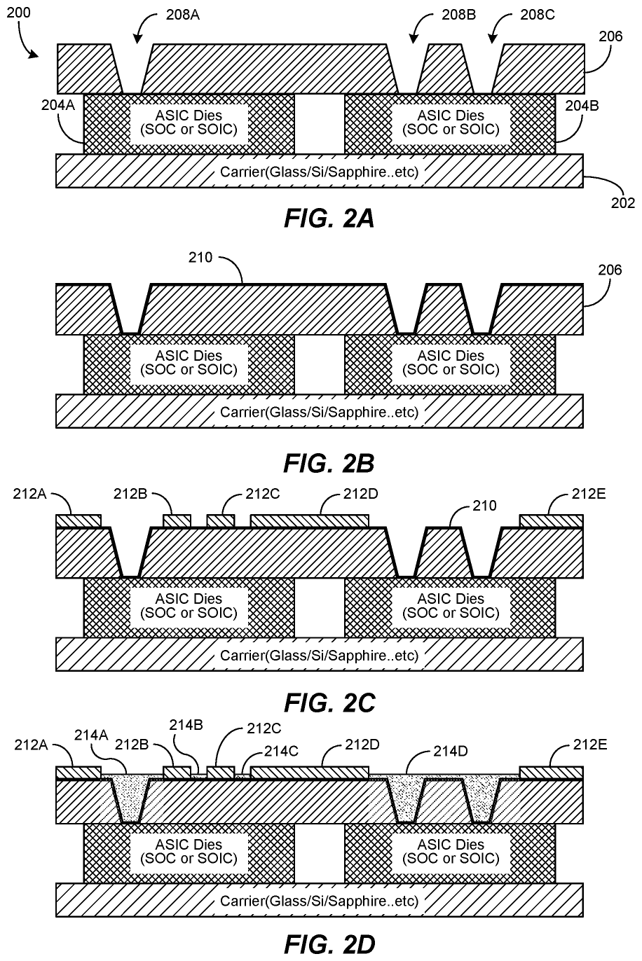

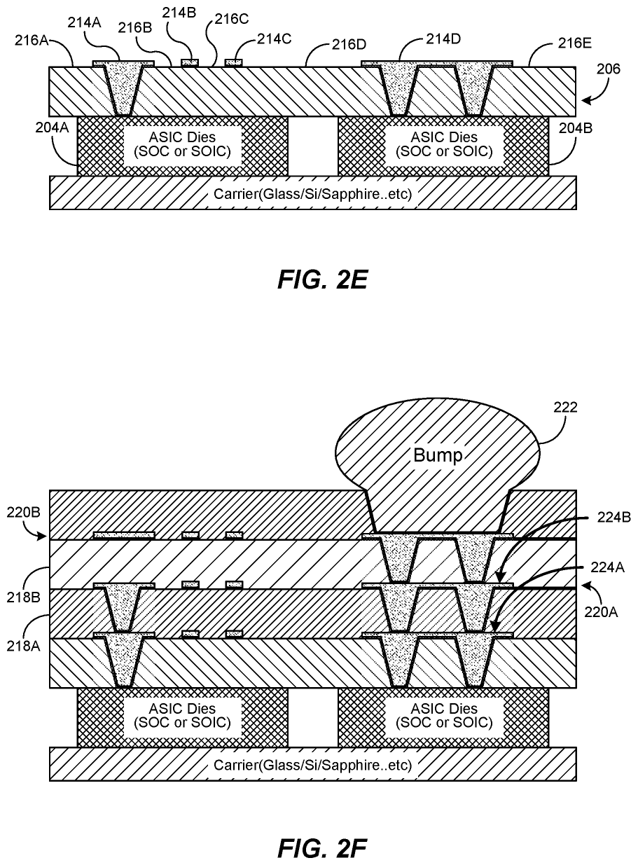

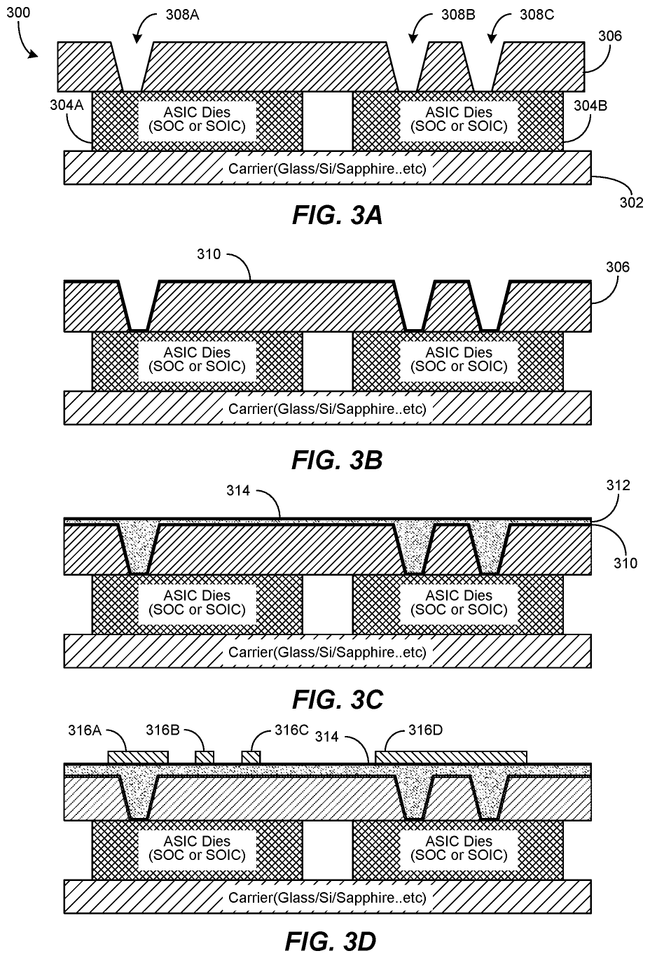

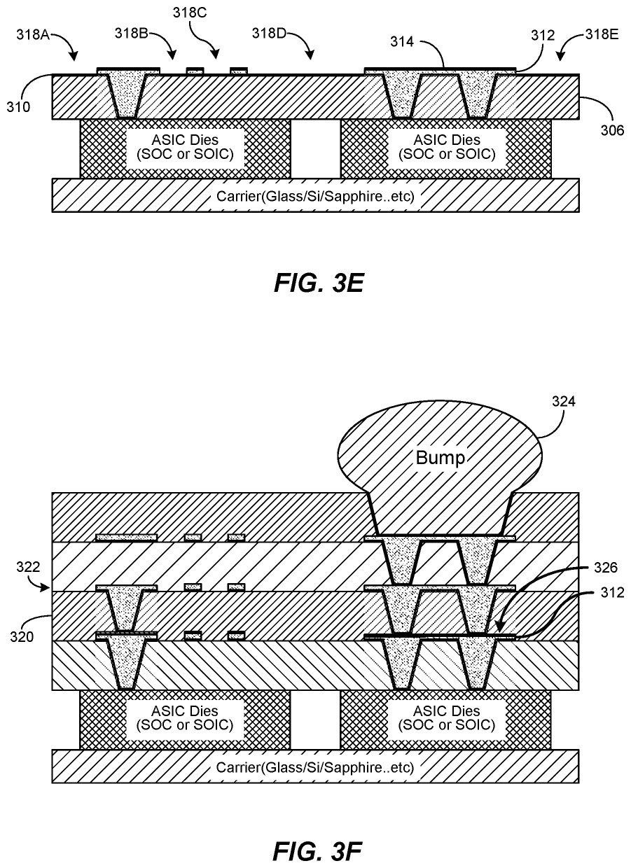

The following will provide, with reference to FIG. 1, detailed descriptions of example methods for reducing semiconductor device delamination. In addition, detailed descriptions of example semiconductor devices will be provided in connection with FIGS. 2A-2F and FIGS. 3A-3F.

In one example, a semiconductor device can include a top barrier layer deposited on top of a metal layer plating a bottom barrier layer and dielectric material deposited on top of the top barrier layer and adjacent to the metal layer and the bottom barrier layer.

Another example can be the previously described example semiconductor device, wherein the top barrier layer, the metal layer, and the bottom barrier layer are subjected to etching.

Another example can be any of the previously described example semiconductor devices, further including a die exposed by the etching.

Another example can be any of the previously described example semiconductor devices, wherein the dielectric material is further deposited on top of the die.

Another example can be any of the previously described example semiconductor devices, further including additional dielectric material exposed by the etching.

Another example can be any of the previously described example semiconductor devices, wherein the dielectric material is further deposited on top of the additional dielectric material.

Another example can be any of the previously described example semiconductor devices, wherein the top barrier layer is deposited on top of the metal layer absent planarization of the metal layer.

Another example can be any of the previously described example semiconductor devices, wherein the metal layer corresponds to a redistribution layer of the semiconductor device.

In one example, a semiconductor device package can include a barrier layer deposited on top of a metal redistribution layer, dielectric material deposited on top of the barrier layer absent planarization of the metal redistribution layer, and a die resting on top of a carrier and electrically connected to the metal redistribution layer.

Another example can be the previously described example semiconductor device package, further including an additional barrier layer plated by the metal redistribution layer, wherein the barrier layer, the metal redistribution layer, and the additional barrier layer are subjected to etching, and the dielectric material is further deposited adjacent to the metal redistribution layer and the additional barrier layer.

Another example can be any of the previously described example semiconductor device packages, wherein the die is exposed by the etching.

Another example can be any of the previously described example semiconductor device packages, wherein the dielectric material is further deposited on top of the die.

Another example can be any of the previously described example semiconductor device packages, further including additional dielectric material exposed by the etching.

Another example can be any of the previously described example semiconductor device packages, wherein the dielectric material is further deposited on top of the additional dielectric material.

In one example, a method can include depositing a top barrier layer on top of a metal layer plating a bottom barrier layer and depositing dielectric material on top of the top barrier layer and adjacent to the metal layer and the bottom barrier layer.

Another example can be the previously described example method, further including subjecting the top barrier layer, the metal layer, and the bottom barrier layer to etching.

Another example can be any of the previously described example methods, wherein the etching exposes a die.

Another example can be any of the previously described example methods, wherein depositing the dielectric material further deposits the dielectric material on top of the die.

Another example can be any of the previously described example methods, wherein the etching exposes additional dielectric material.

Another example can be any of the previously described example methods, wherein depositing the dielectric material further deposits the dielectric material on top of the additional dielectric material.

FIG. 1 is a flow diagram of an example method 100 for reducing semiconductor device delamination. At step 102, method 100 can deposit a top barrier layer. For example, step 102 can include depositing a top barrier layer on top of a metal layer plating a bottom barrier layer.

The term “barrier layer,” as used herein, can generally refer to a film deposited between layers of a semiconductor device to prevent silicon diffusion into a layer of metallization. For example, and without limitation, barrier layer can refer to a diffusion barrier, a film, a seed layer, etc. Material of the barrier layer can vary, with example materials including Ti, TiN, Ni, TaN, etc. A barrier layer can be deposited using various types of processes, such as physical vapor deposition. Such deposition can be performed atop a lower layer before addition of a layer of metallization, and/or atop a layer of metallization before addition of a higher layer. Lower and/or higher layers can include, for example, dies, carriers, substrates, dielectric material, C4 bumps, solder balls, etc.

The term “metal layer,” as used herein, can generally refer to a layer of metallization deposited on a wafer to form one or more conductive pathways. For example, and without limitation, such layers of metallization can include aluminum, nickel, chromium, gold, germanium, copper, silver, titanium, tungsten, platinum, tantalum, selected metal alloys, etc. Metallization can often be accomplished with a vacuum deposition technique.

The systems described herein can perform step 102 in a variety of ways. In one example, step 102 can include using physical vapor deposition to deposit a thin barrier material (e.g., Ti, TiN, Ni, TaN, etc.) on top of a metal layer (e.g., Cu, Al, etc.). In some examples, step 102 can include depositing the top barrier layer on top of the metal layer absent planarization (e.g., polishing) of the metal layer. In some examples, depositing the top barrier layer at step 102 can accomplish formation of a sandwich structure in which the metal layer is sandwiched between the bottom barrier layer and the top barrier layer. In some examples, the metal layer can plate a via formed in a lower layer (e.g., wafer (e.g., additional dielectric material, die, carrier, substrate, etc.). Additionally or alternatively, the metal layer can form a redistribution layer on top of the lower layer (e.g., additional dielectric material). In various implementations, size of a via can be in a range of five to fifteen micrometers and have a spacing in a range of five to fifteen micrometers. Additionally or alternatively, via height can be in a range of five to fifteen micrometers. In various implementations, top barrier layer thickness and/or bottom barrier layer thickness can be in a range of one-half to five micrometers. In various implementations, total sandwich structure thickness can be in a range of two to fifteen micrometers. Alternatively or additionally, the sandwich structure can be implemented in any redistribution layer and redistribution layer routing can be at any angle. Alternatively or additionally, redistribution layer height can be in a range of one to ten micrometers. In various implementations, a redistribution layer pad enclosure on a bottom via can be in a range of one to three micrometers per side. In various implementations, one or more sandwich structures can be located beneath another via, a C4 bump, and/or a solder ball.

At step 104, method 100 can deposit dielectric material. For example, step 104 can include depositing dielectric material on top of the top barrier layer and adjacent to the metal layer and the bottom barrier layer.

The term “dielectric material,” as used herein, can generally refer to a poor conductor of electricity but an efficient supporter of electrostatic fields. For example, and without limitation, dielectric material can store electrical charges and have a high specific resistance and a negative temperature coefficient of resistance. Dielectric films can be used in semiconductor technology for masking against the diffusion of dopants into semiconductors, fabrication of active and passive components, electrical isolation between components, and surface passivation of devices. Example types of dielectric material can include, without limitation, silica, silicon nitride, silicon dioxide, hafnium silicate, zirconium silicate, aluminum oxide, barium titanate, etc.

The systems described herein can perform step 104 in a variety of ways. In one example, step 104 can include subjecting the top barrier layer, the metal layer, and the bottom barrier layer to etching. In various implementations of this example, step 104 can include performing dry metal etching. For example, step 104 can include performing lithography to deposit photoresist on a space area of a redistribution layer (e.g., atop one or more vias and/or one or more redistribution layer lines) and performing dry metal etching that defines the redistribution layer space area by removing the top barrier layer, the metal layer, and the bottom barrier layer in areas not protected by the photoresist. As a result of the etching, only a top and a bottom of the redistribution layer metal can be covered by the barrier layers, while a sidewall of the redistribution layer metal can be exposed. In some examples, step 104 can expose a lower layer (e.g., additional dielectric material, a die, a substrate, a carrier, etc.). In various implementations, redistribution layer width can be in a range of one to ten micrometers and redistribution layer spacing can be in a range of one to ten micrometers. Alternatively or additionally, step 104 can include depositing the dielectric material using a low-pressure technique (e.g., evaporation, sputtering, plasma deposition, low-pressure chemical vapor deposition, etc.). Alternatively or additionally, step 104 can include depositing the dielectric material using one or more techniques operating at one atmosphere total pressure (e.g., thermal oxidation, chemical vapor deposition, anodization, electrophoresis, spin on, spray on, silk screening, etc.). Alternatively or additionally, step 104 can include depositing the dielectric material using one or more miscellaneous techniques (e.g., roller coating, offset printing, centrifugation-sedimentation, transfer, etc.). In some examples in which the etching exposes a lower layer, step 104 can include depositing the dielectric material on top of the lower layer (e.g., additional dielectric material, a die, a substrate, a carrier, etc.).

The term “etching,” as used herein, can generally refer to selective removal of material. For example, and without limitation, etching can refer to selective removal of material from a thin film on a substrate (with or without prior structures on its surface) to create a pattern of that material on the substrate. Example types of etching can include dry etching and wet etching. For example, wet etching can refer to a process of removing a material chemically with a liquid reactant and can involve a chemical which dissolves the material to be etched. In contrast, dry etching can refer to the removal of material, typically a masked pattern of semiconductor material, by exposing the material to a bombardment of ions (e.g., a plasma of reactive gases (e.g., fluorocarbons, oxygen, chlorine, boron trichloride, etc.) that are sometimes combined with nitrogen, argon, helium, etc.) that dislodge portions of the material from the exposed surface. A common type of dry etching is reactive-ion etching, which can also be referred to as dry metal etching. Unlike most wet etching techniques, the dry etching process typically etches directionally or anisotropically.

Referring generally to FIGS. 2A-2F, an example semiconductor device 200 is shown at various stages of manufacture. For example, as shown in FIG. 2A, semiconductor device 200 can include a carrier 202 (e.g., glass, silicon, sapphire, etc.) on which a plurality of dies 204A and 204B (e.g., application specific integrated circuits (ASICs), systems on chip (SoCs), small outline integrated circuits (SOICs), etc.) can rest. Semiconductor device 200 can also include a layer of dielectric material 206 deposited atop the dies 204A and 204B. Dielectric material 206 can have one or more vias 208A-208C formed therein by, for example, polyimide lithography. A mold material can also be located adjacent to and/or between dies 204A and 204B.

The example semiconductor device 200 of FIG. 2A can undergo a process to add a redistribution layer. For example, as shown in FIG. 2B, a barrier layer 210 can be deposited on the dielectric material 206. Then, as shown in FIG. 2C, redistribution layer line lithography can be performed by depositing photoresist 212A-212E in selected areas atop the barrier layer 210. Next, as shown in FIG. 2D, metal plating can be performed by adding a metal layer 214A-214D atop the barrier layer in areas thereof not covered by photoresist 212A-212E, thus forming metal plated vias and redistribution layer lines. Subsequently, as shown in FIG. 2E, the photoresist can be removed, and the barrier layer can be subjected to etching in areas 216A-216E thereof not covered by metal layer 214A-214D. Selectively removing the barrier layer in this manner can improve electrical isolation of the plated vias and redistribution layer lines from one another and/or can aid in heat dissipation rising from the dies 204A and 204B through the dielectric material 206.

The example semiconductor device 200 of FIG. 2A, having undergone the process to add a redistribution layer as shown in FIGS. 2B-2E, can, as shown in FIG. 2F, undergo additional procedures to add more dielectric layers 218A and 218B, more redistribution layers 220A and 220B, and one or more connection elements 222 (e.g., solder balls and/or C4 bumps). The resulting semiconductor device can experience delamination in one or more areas, such as location 224A and 224B, because the dielectric material does not experience strong adhesion to the metal layers.

Referring generally to FIGS. 3A-3F, an example semiconductor device 300 is shown at various stages of manufacture. For example, as shown in FIG. 3A, semiconductor device 300 can include a carrier 302 (e.g., glass, silicon, sapphire, etc.) on which a plurality of dies 304A and 304B (e.g., application specific integrated circuits (ASICs), systems on chip (SoCs), small outline integrated circuits (SOICs), etc.) can be located. Semiconductor device 300 can also include a layer of dielectric material 306 (e.g., additional dielectric material referenced in step 104 of method 100 of FIG. 1) deposited atop the dies 304A and 304B. Dielectric material 306 can have one or more vias 308A-308C formed therein by, for example, polyimide lithography. A mold material can also be located adjacent to and/or between dies 304A and 304B.

The example semiconductor device 300 of FIG. 3A can undergo a process to add a redistribution layer. For example, as shown in FIG. 3B, a bottom barrier layer 310 can be deposited on the dielectric material 306. Then, as shown in FIG. 3C, metal plating can be performed by adding a metal layer 312 atop an entirety of the bottom barrier layer 310, and a top barrier layer 314 can be deposited on the metal layer 312, thus forming the aforementioned sandwich structure. Advantageously, the top barrier layer 314 can be deposited on the metal layer 312 absent planarization (e.g., polishing) of the metal layer 312, thus reducing manufacturing costs. Next, as shown in FIG. 3D, redistribution layer line lithography can be performed by depositing photoresist 316A-316D in selected areas atop the top barrier layer 314. Subsequently, as shown in FIG. 3E, etching (e.g., dry metal etching) can be performed to remove the top barrier layer 314, the metal layer 312, and the bottom barrier layer 310 in areas 318A-318E not covered by the photoresist, and the photoresist can be removed. Subjecting the top barrier layer 314, the metal layer 312, and the bottom barrier layer 310 to etching in this manner can form plated vias and redistribution layer lines and expose a lower layer, such as the dielectric material 306. Subjecting the top barrier layer 314, the metal layer 312, and the bottom barrier layer 310 to etching in this manner can also expose a sidewall of the metal layer 312.

The example semiconductor device 300 of FIG. 3A, having undergone the process to add a redistribution layer as shown in FIGS. 3B-3E, can, as shown in FIG. 3F, undergo additional procedures to add more dielectric layers, such as dielectric layer 320 (e.g., dielectric material referenced in step 104 of FIG. 1), more redistribution layers, such as redistribution layer 322, and one or more connection elements 324 (e.g., solder balls and/or C4 bumps). Addition of the dielectric layer 320 can deposit dielectric material atop the top barrier layer and adjacent to the metal layer 312 (e.g., in contact with the exposed sidewall of the metal layer 312) and the bottom barrier layer. Addition of the dielectric layer 320 can also deposit dielectric material atop the layer of dielectric material 306. The resulting semiconductor device can experience reduced delamination in one or more areas, such as location 326, because the top barrier layer improves adhesion of the dielectric material of dielectric layer 320 to the metal layer 312. The disclosed sandwich structure can be implemented in any or all redistribution layers in the semiconductor device on an as needed basis to reduce delamination observed during operation of similar semiconductor devices.

As set forth above, systems and methods for reducing semiconductor device delamination are disclosed herein. For example, by depositing a top barrier layer on top of a metal layer plating a bottom barrier layer and depositing dielectric material on top of the top barrier layer and adjacent to the metal layer and the bottom barrier layer, the top barrier layer can promote adhesion of the dielectric material to a lower layer, reduce delamination, and improve performance of a semiconductor device.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A semiconductor device, comprising:
a top barrier layer deposited on top of a metal layer plating a bottom barrier layer; and
dielectric material deposited on top of the top barrier layer and adjacent to the metal layer and the bottom barrier layer.

2. The semiconductor device of claim 1, wherein the top barrier layer, the metal layer, and the bottom barrier layer are subjected to etching.

3. The semiconductor device of claim 2, further comprising a die exposed by the etching.

4. The semiconductor device of claim 3, wherein the dielectric material is further deposited on top of the die.

5. The semiconductor device of claim 2, further comprising additional dielectric material exposed by the etching.

6. The semiconductor device of claim 5, wherein the dielectric material is further deposited on top of the additional dielectric material.

7. The semiconductor device of claim 1, wherein the top barrier layer is deposited on top of the metal layer absent planarization of the metal layer.

8. The semiconductor device of claim 1, wherein the metal layer corresponds to a redistribution layer of the semiconductor device.

9. A semiconductor device package, comprising:
a barrier layer deposited on top of a metal redistribution layer;
dielectric material deposited on top of the barrier layer absent planarization of the metal redistribution layer; and
a die resting on top of a carrier and electrically connected to the metal redistribution layer.

10. The semiconductor device package of claim 9, further comprising:
an additional barrier layer plated by the metal redistribution layer, wherein the barrier layer, the metal redistribution layer, and the additional barrier layer are subjected to etching, and the dielectric material is further deposited adjacent to the metal redistribution layer and the additional barrier layer.

11. The semiconductor device package of claim 10, wherein the die is exposed by the etching.

12. The semiconductor device package of claim 11, wherein the dielectric material is further deposited on top of the die.

13. The semiconductor device package of claim 10, further comprising:
additional dielectric material exposed by the etching.

14. The semiconductor device package of claim 13, wherein the dielectric material is further deposited on top of the additional dielectric material.

15. A method comprising:
depositing a top barrier layer on top of a metal layer plating a bottom barrier layer; and
depositing dielectric material on top of the top barrier layer and adjacent to the metal layer and the bottom barrier layer.

16. The method of claim 15, further comprising:
subjecting the top barrier layer, the metal layer, and the bottom barrier layer to etching.

17. The method of claim 16, wherein the etching exposes a die.

18. The method of claim 17, wherein depositing the dielectric material further deposits the dielectric material on top of the die.

19. The method of claim 16, wherein the etching exposes additional dielectric material.

20. The method of claim 19, wherein depositing the dielectric material further deposits the dielectric material on top of the additional dielectric material.
